(19) United States
(12) Patent Application Publication
(10) Pub. No.: US 2024/0235505 A1
(43) Pub. Date: Jul. 11, 2024

(54) CIRCUIT FOR DEVICE TEMPERATURE PROTECTION

(71) Applicant: ams-OSRAM Asia Pacific Pte. Ltd., Singapore (SG)

(72) Inventors: Ivan SEJC, Graz (AT); Cheng ZHANG, Graz (AT)

(21) Appl. No.: 18/563,890

(22) PCT Filed: May 27, 2022
(86) PCT No.: PCT/SG2022/050359

§ 371 Date: Nov. 23, 2023

(30) Foreign Application Priority Data
May 27, 2021 (GB) 2107532.0

(51) Int. Cl. H03F 3/45; H03F 1/26

(52) U.S. Cl. CPC H03F 3/45968; H03F 1/26; H03F 2200/468

(57) ABSTRACT

A circuit for device temperature protection is disclosed. The circuit comprises a Proportional-To-Absolute-Temperature (PTAT) voltage generator. The circuit also comprises at least one comparator. The PTAT voltage generator is configured to apply offset cancellation in a first clock phase. The at least one comparator is configured to evaluate an output of the PTAT generator in a second clock phase. A method of temperature protection of a device is also disclosed.

### CROSS REFERENCE TO RELATED APPLICATIONS

This is a national phase of PCT Application PCT/SG2022/050359, filed on May 27, 2022, which claims priority to British application GB 2107532.0, the entire contents of each of which are incorporated herein by reference.

### TECHNICAL FIELD

The present disclosure relates to the field of temperature protection of devices, and relates in particular to a circuit based on a Proportional-To-Absolute-Temperature (PTAT) voltage generator.

### BACKGROUND

Temperature protection of devices, e.g. integrated circuits, may be required in a wide range of applications, such as consumer electronics devices, automotive devices, power management devices, etc.

Such devices may comprise circuitry that, in use, may increase in temperature. For example, when heat generated as a result of leakage and active power from a device exceeds a heat dissipation capacity of a package or environment of the device, a temperature of the device may rise substantially. In such cases, a performance of the device may be affected and, in extreme cases, the device may be damaged.

It is known to integrate circuits into a device to determine a temperature of the device to prevent any temperature related performance degradation or damage. Such circuits may indicate if a temperature of the device exceeds a predetermined temperature range, i.e., the device becomes too hot or cold. However, known circuits may exhibit a limited accuracy. Furthermore, such circuits may also require calibration. Calibration of the device may be performed during an initial production or testing phase or throughout a lifetime of the device, e.g. at device start-up.

Calibration in a manufacturing environment may be relatively slow, complex, generally inefficient, and thereby costly. For example, in some instances calibration must rely on a measurement of at least two precise temperature points. However, achieving a precise ambient temperature in a production test environment may take a relatively long time, thus potentially increasing a cost of a device.

Furthermore, it may be difficult to ensure that a temperature is uniform across multiple devices, e.g. multiple devices on a single substrate prior to dicing, potentially introducing errors into a calibration process.

Calibration, particularly if implemented throughout the lifetime of the device, may also require implementation of complex circuitry, such as analog-to-digital converters.

Such circuitry may increase a size, and thus a cost, of a device.

It is therefore desirable to provide a device, such as an integrated circuit, that is protected against operation outside a defined temperature range with a high degree of precision and accuracy. It is desired that such a device can be manufactured at a relatively low cost. It is further desired that solution does not substantially increase a size, and thereby cost, of the device.

It is therefore an aim of at least one embodiment of at least one aspect of the present disclosure to obviate or at least mitigate at least one of the above identified shortcomings of the prior art.

### BRIEF SUMMARY

The present disclosure relates to the field of temperature protection of devices, and relates in particular to a circuit based on a Proportional-To-Absolute-Temperature (PTAT) voltage generator. This disclosure also relates to method of temperature protection of such devices.

According to a first aspect of the disclosure, there is provided a circuit for device temperature protection comprising a PTAT voltage generator and at least one comparator. The PTAT voltage generator is configured to apply offset cancellation in a first clock phase, and the at least one comparator is configured to evaluate an output of the PTAT voltage generator in a second clock phase.

Advantageously, by evaluating the output of the PTAT voltage generator only in each second clock phase, the first clock phase may effectively be used to remedy potential errors in the generation of the output of the PTAT voltage generator, thereby mitigating a requirement for a separate calibration of the circuit.

Advantageously, by mitigating a requirement for a separate calibration of the circuit, complex circuitry such as analog-to-digital circuitry that may otherwise have been required for calibration purposes, may not be required.

Advantageously, by continually addressing errors in the circuit on each first clock phase, an overall accuracy and responsiveness of the circuit may be improved relative to circuits that are calibrated only periodically, only at start-up, or only in a production phase.

The PTAT voltage generator may comprise an operational transconductance amplifier (OTA). The offset cancellation may be applied to the PTAT voltage generator by chopper stabilization of the OTA.

Advantageously, by applying such offset cancellation to the to the PTAT voltage generator, an error contribution of the OTA to a voltage generated by the PTAT voltage generator in the second clock phase may be reduced.

The at least one comparator may be configured to apply offset cancellation by auto-zeroing during the first clock phase.

Advantageously, by applying offset cancellation to the comparator, an error contribution of the comparators to an evaluation of the output of the PTAT voltage generator in the second clock phase may be reduced.

The particular auto-zeroing technique implemented may be one of several known to a person skilled in the art and is therefore not described in detail. For example, in a simplistic design of a circuit for an auto-zeroing comparator, in the first clock phase the comparator may be configured in a closed-loop configuration and a difference between a reference voltage and an offset may be stored in a capacitor. In the second clock phase, the comparator may be configured in an open-loop configuration, and the stored voltage on the capacitor makes the comparator almost offset free when an input signal is compared with a reference voltage.

The circuit may comprise a latch configured to latch an output from the at least one comparator at an end of the second clock phase.

Advantageously, by latching the output from the at least one comparator at an end of the second clock phase, the output from the comparator may have been given a maximum amount of available time to stabilize before being latched.

The PTAT voltage generator comprises a bipolar core configured to generate a current for generating the output of the PTAT voltage generator.

It will be understood that the term ‘bipolar core’ refers to at least two bipolar junction transistors (BJTs). In an example of a bipolar core comprising two integrated BJTs, a base-emitter voltage of a first BJT will decrease with increasing temperature. A difference in base-emitter voltages between the first BJT and a second BJT having a constant current ratio will increase with increasing temperature, and thus may be utilized in generation of a PTAT voltage.

The PTAT voltage generator may comprise first and second transistors configured as a current mirror to mirror the current.

The PTAT voltage generator may comprise a notch filter. The notch filter may be configured to filter an output from the OTA. An output of the notch filter may be coupled to a gate of the first and second transistors.

The notch filter may be configured to filter an output from the OTA during the first clock phase. The notch filter may be configured to operate only during the first clock phase. That is, the notch filter may be disabled during the second clock phase, as described in more detail below.

The PTAT voltage generator may comprise a chopper coupled to a first output and a second output of the current mirror. The second output of the current mirror may correspond to a mirrored current.

In the second clock phase the chopper may be configured to couple the first output of the current mirror to a resistor to generate a voltage corresponding to the output of the PTAT voltage generator.

Advantageously, by coupling the first output of the current mirror, e.g. a drain of the first transistor, a more precise voltage output of the PTAT voltage generator may be provided. That is, instead of basing a voltage output of the PTAT voltage generator on a mirrored current, as may be the case if the second output of the current mirror was coupled, the voltage output of the PTAT voltage generator is based on a current directly related to the current generated by the bipolar core.

In the second clock phase the chopper may be configured to couple the second output of the current mirror to the bipolar core.

Advantageously, coupling the second output of the current mirror, e.g. the mirrored current, to the bipolar core may help more quickly stabilize an output of the PTAT voltage generator circuit in the first clock phase of the next clock period.

In the first clock phase the chopper may be configured to couple the second output of the current mirror to the resistor.

In the first clock phase the chopper may be configured to couple the first output of the current mirror to the bipolar core, thus enabling the offset cancellation of the OTA, as described in more detail below.

The circuit may comprise a plurality of comparators. Each comparator may be configured to evaluate a respective output of the PTAT voltage generator in the second clock phase by comparing the respective output to a respective reference voltage.

Advantageously, by implementing such a plurality of comparators, multiple temperature thresholds may be defined. For example, a threshold may be defined corresponding to a warning that an over-temperature condition is being reached. In another example, a threshold may be defined corresponding to an over-temperature condition, wherein the device may be configured to react, such as by reducing functionality, clock speed, or the like to reduce a temperature of the device.

In the second clock phase the chopper may be configured to couple the first output of the current mirror to a series of resistors to generate voltages corresponding to the respective outputs of the PTAT voltage generator.

Advantageously, such an arrangement enables multiple thresholds to be defined based on the output from a single PTAT voltage generator.

The at least one comparator may be configured to compare an output of the PTAT voltage generator to a reference voltage to determine whether a temperature of the device has exceeded a limit.

According to a second aspect of the disclosure, there is provided a method of temperature protection of a device, the method comprising:
configuring a PTAT voltage generator in a circuit to apply offset cancellation in a first clock phase; and
configuring at least one comparator in the circuit to evaluate an output of the PTAT voltage generator in a second clock phase.

Advantageously, by configuring at least one comparator in the circuit to evaluate an output of the PTAT voltage generator only in a second clock phase, the first clock phase may effectively be used to remedy potential errors in the generation of the output of the PTAT voltage generator, thereby mitigating a requirement for a separate calibration of the circuit.

Advantageously, by mitigating a requirement for a separate calibration of the circuit, complex circuitry such as analog-to-digital circuitry that may otherwise have been required for calibration purposes, may not be required.

Advantageously, by continually addressing errors in the circuit on each first clock phase, an overall accuracy and responsiveness of the circuit may be improved relative to circuits that are calibrated only periodically, only at start-up, or only in a production phase.

The method may comprise applying the offset cancellation by chopper stabilization of an OTA in the PTAT voltage generator.

The method may comprise applying offset cancellation to the at least one comparator by auto-zeroing during the first clock phase.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

These and other aspects of the present disclosure will now be described, by way of example only, with reference to the accompanying drawings, wherein:

FIG. 1 depicts a prior art device temperature protection circuit;

FIG. 2 depicts a prior art calibration method for a device temperature protection circuit;

FIG. 3A depicts a block diagram of a circuit for device temperature protection according to an embodiment of the disclosure;

FIG. 3B depicts a timing diagram corresponding to operation of the circuit of FIG. 3, according to an embodiment of the disclosure

FIG. 4 depicts a circuit for device temperature protection according to an embodiment of the disclosure;

FIG. 5 depicts a timing diagram corresponding to operation of the circuit of FIG. 4, according to an embodiment of the disclosure

FIG. 6 depicts an example of a chopper as implemented in the circuit of FIG. 4;

FIG. 7 depicts a device comprising a circuit for device temperature protection according to an embodiment of the disclosure; and

FIG. 8 depicts a method of temperature protection of a device, according to an embodiment of the disclosure.

### DETAILED DESCRIPTION

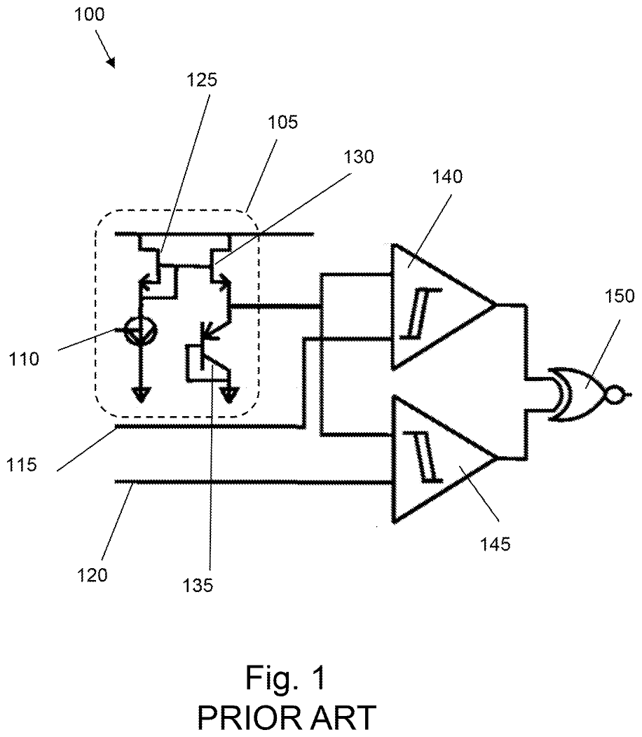

FIG. 1 depicts a prior art device temperature protection circuit 100. The circuit 100 comprises CTAT sub-circuit 105 for generating a voltage Complementary To Absolute Temperature (CTAT). The circuit also comprises a reference current input 110, a first constant reference voltage input 115 and a second constant reference voltage input 120. In an example, the first constant reference voltage input 115 may be at a lower voltage than the second constant reference voltage input 120. The first and second reference voltage inputs 115, 120 may, for example, be provided by one or more separate band-gap reference voltage circuits (not shown).

The CTAT sub-circuit 105 comprises a first transistor 125 and a second transistor 130, arranged to form a current mirror. The CTAT sub circuit 105 also comprises a bipolar transistor 135, configured such that an emitter-base voltage of the bipolar transistor 135 exhibits a negative temperature coefficient.

The circuit 100 comprises a first comparator 140. An emitter of the bipolar transistor 135 is coupled to a first input of the first comparator 140. The first constant reference voltage input 115 is coupled to a second input of the first comparator 140. As such, the first comparator 140 is configured to compare the voltage at the emitter of the bipolar transistor 135 to the first constant reference voltage input 115

As such, the first comparator 140 may, for example, be configured to indicate an under-temperature condition.

The circuit 100 comprises a second comparator 145. An emitter of the bipolar transistor 135 is coupled to a first input of the second comparator 145. The second constant reference voltage input 120 is coupled to a second input of the second comparator 145. As such, the second comparator 145 is configured to compare the voltage at the emitter of the bipolar transistor 135 to the second constant reference voltage input 120

As such, the second comparator 145 may, for example, be configured to indicate an over-temperature condition.

In the example circuit 100 of FIG. 1, an output from the first comparator 140 and an output from the second comparator 145 are coupled to inputs of an exclusive NOR gate 150. As such, an output from the exclusive NOR gate 150 may indicate occurrence of either the under-temperature condition or the over-temperature condition.

However, for such a circuit 100 implemented in a CMOS technology, due to a spread of the input current and a saturation current of the bipolar transistor 135, the above-described temperature dependency of emitter-base voltage of the bipolar transistor 135 may demonstrate a large spread, thereby introducing an error into indications of under/over temperature conditions.

Moreover, any offset associated with the first comparator 140 and/or the second comparator 145 may also contribute to errors in the temperature protection, thereby reducing an accuracy of the circuit 100.

Due to the relatively low accuracy of such conventional device temperature protection circuits 100, it may be necessary to calibrate the circuit 100.

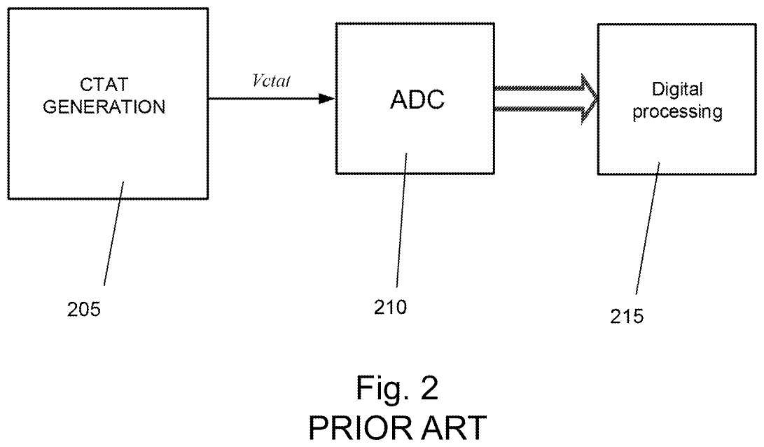

FIG. 2 depicts a prior art calibration method for a device temperature protection circuit.

In the example of FIG. 2, a CTAT voltage generator circuit 205 generates a voltage, denoted V_{ctat} which is sampled by an analog-to-digital converter (ADC) 210. A digital value corresponding to the sample V_{ctat} may then be processed and calibrated in a digital domain, e.g. by a processor 215 running software, or by a state machine.

However, due to variations in V_{ctat} generation and any voltage offsets due to the ADC 210, the calibration must rely on measurements of V_{ctat} made at two distinct and precise temperature points.

However, performing such a calibration in a manufacturing environment may be relatively slow, complex, generally inefficient and thereby costly. For example, to perform a measurement at two precise temperature points would require precise ambient temperature control in a production environment, incurring delays and costs in a manufacturing process.

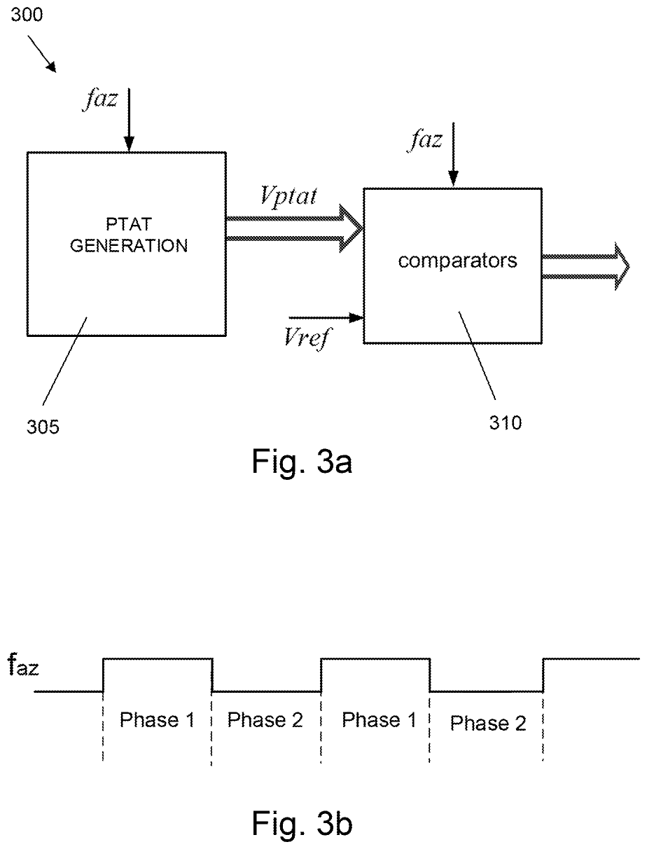

FIG. 3A depicts a block diagram of a circuit 300 for device temperature protection according to an embodiment of the disclosure.

The circuit 300 comprises a Proportional-To-Absolute-Temperature (PTAT) voltage generator 305. The circuit 300 also comprises at least one comparator 310.

A clock signal is provided to the circuit 300. The clock signal has a frequency denoted f_{az}.

The circuit 300 is configured such that the PTAT voltage generator 305 is configured to apply offset cancellation in a first clock phase.

An output of the PTAT voltage generator 305, denoted Vₚₜₐₜ is provided as an input to the at least one comparator 310.

A reference voltage, denoted V_{ref}, is also provided to the at least one comparator 310. The reference voltage V_{ref} may, for example, be provided by or derived from, a band-gap voltage generator circuit

The at least one comparator is configured to evaluate the output of the PTAT voltage generator Vₚₜₐₜ in a second clock phase, e.g. compare the output of the PTAT voltage generator Vₚₜₐₜ to the reference voltage V_{ref}.

FIG. 3B depicts the clock signal having the frequency denoted f_{az}. For purposes of example, when the clock signal is at a logic ‘high’ level, the clock signal is in the first phase, denoted “Phase 1”. When the clock signal is at a logic ‘low’ level, the clock signal is in the second phase, denoted “Phase 2”.

Although a 50% duty cycle is depicted in FIG. 3A, a circuit 300 having a clock signal exhibiting a duty cycle greater than or less than 50% also falls within the scope of the disclosure.

In some embodiments, the at least one comparator 310 may be configured to apply offset cancellation by auto-zeroing during the first clock phase.

That is, the circuit 300 operates alternately in the first phase and the second phase of the clock signal. During the first phase, dynamic offset cancellation is applied to PTAT voltage generator and, in some embodiments, also to the at least one comparator 310. During the second phase, the PTAT voltage generator 305 output is evaluated by the at least one comparators. Furthermore, at the end of phase 2, the results of the evaluation are latched. As a result, the circuit 300 may be configured to provide a high accuracy of temperature protection, without requiring any calibration.

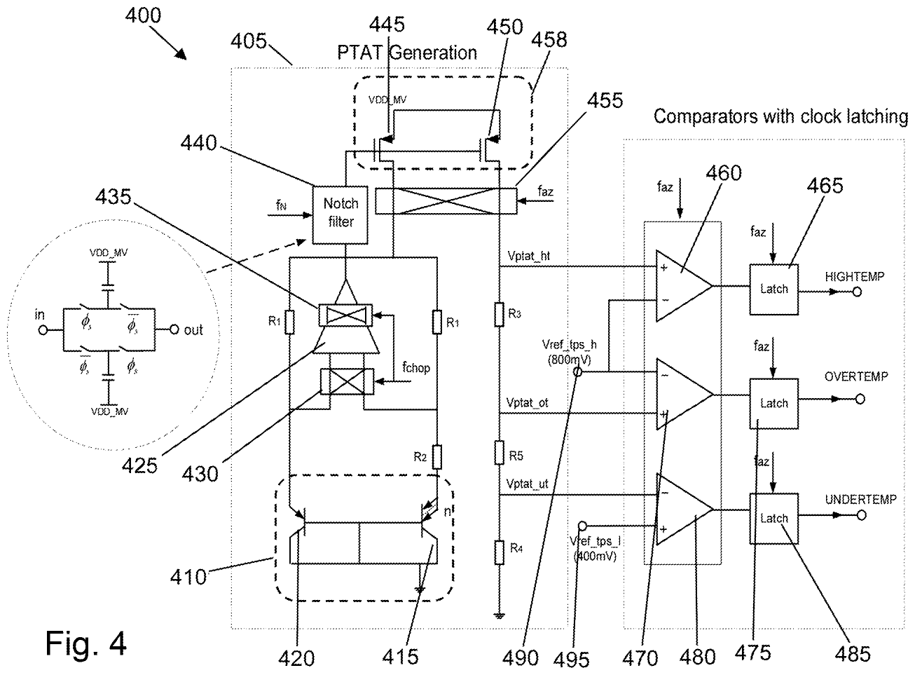

FIG. 4 depicts a circuit 400 for device temperature protection according to an embodiment of the disclosure.

The circuit 400 comprises a PTAT voltage generator 405.

The PTAT voltage generator 405 comprises a bipolar core 410. The bipolar core 410 and a resistor R2 are configured to generate a current for generating the output of the PTAT voltage generator 405.

The bipolar core 410 comprises a first BJT 415 and a second BJT 420 configured such that a difference in base-emitter voltages between the first BJT 415 and the second BJT 420 having a constant current ratio will increase with increasing temperature. A difference in base-emitter voltages between the first BJT 415 and the second BJT 420 having a constant current ratio will increase with increasing temperature, and thus may be utilized in generation of a PTAT voltage.

The PTAT voltage generator 405 also comprises an operational transconductance amplifier (OTA) 425. The OTA 425 is a chopped OTA 425, i.e., offset cancellation is applied to the PTAT voltage generator 405 by chopper stabilization of the OTA 425.

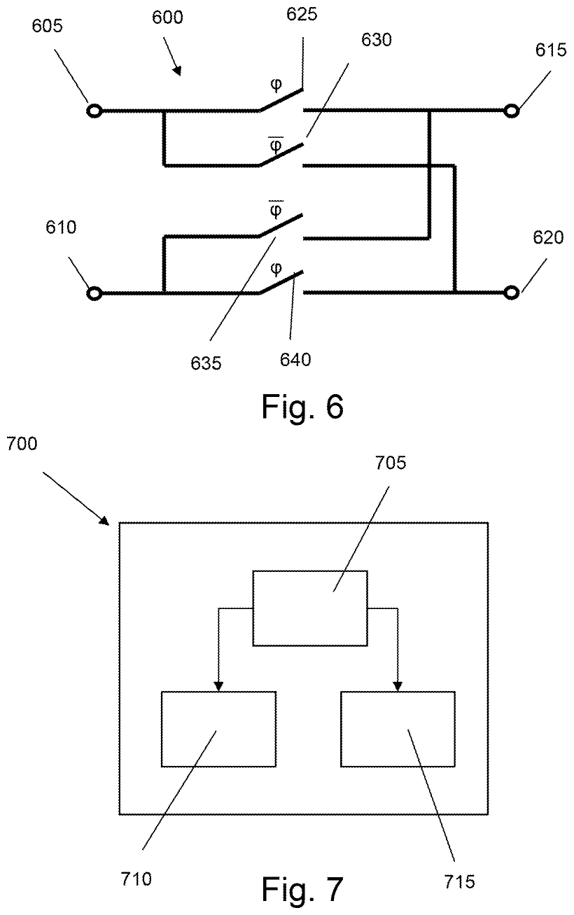

The OTA 425 is chopper stabilized by a first chopper 430 and a second chopper 435. The first and second choppers 430 and 435 are clocked with a clock signal having a chopping frequency denoted f_{chop}. General operation of a chopper is described below with reference to FIG. 6.

The OTA input signal is modulated by the first chopper 430, and then demodulated by the second chopper 435. The offset of the OTA 425 is only modulated by the second chopper 435. Such chopping results in offset cancellation and generally improved noise performance within a low frequency band, while at the same time ensuring the normal signal processing of the OTA 425.

The modulation of the offset of the OTA 425 by the second chopper 435 results in ripple at the output of the OTA 425. As such, the PTAT voltage generator 405 also comprises a notch filter 440 configured to filter an output from the OTA 425.

In the example of FIG. 4, the notch filter 440 is a switched-capacitor notch filter 440. An operating clock frequency fₙ of the notch filter 440 is half of the chopping frequency f_{chop}, and the sampling occurs at both positive and negative edge of the operating clock, thereby effectively smoothing ripples from the output of the OTA 425.

The PTAT voltage generator 405 comprises a first transistor 445 and a second transistor 450 configured as a current mirror 458. An output of the notch filter 440 coupled to a gate of the first and second transistors 445, 450.

As such, the current mirror 458 is configured to mirror the current generated by the bipolar core 410 and the resistor R2.

A third chopper 455 is coupled to the current mirror 458. That is, a drain of the first transistor 445 is coupled to a first input of the third chopper 455 and a drain of the second transistor 450 is coupled to a second input of the third chopper 455.

A first output of the third chopper 455 is coupled to the bipolar core 410 via a resistors denoted R1. A second output of the chopper is coupled to a series of resistors denoted R3, R4 and R5. That is, a current from the output of the current mirror 458 may be coupled by the chopper to the series of the resistors R3, R4 and R5 to generate several PTAT voltages, which as described below may be compared to different reference voltages to identify certain temperature conditions.

The third chopper 455 corresponds to the example chopper 600 depicted in FIG. 6, and is clocked with a clock signal having a frequency denoted f_{az}.

The second output of the third chopper 455 is coupled to a first input of a first comparator 460, and in the example of FIG. 4 the signal to the first input of the first comparator 460 is denoted V_{ptat_ht}, and corresponds to a voltage generated at resistor R3. A second input of the first comparator 460 is coupled to a first reference voltage 490. The first reference voltage 490 may, for example, be provided by one or more separate band-gap reference voltage circuits (not shown). In the example of FIG. 4, the first reference voltage 490 is 800 mV.

The first comparator 460 is configured to apply offset cancellation by auto-zeroing during the first clock phase of the clock signal having the frequency denoted f_{az}. In the second phase of the clock signal having the frequency denoted f_{az}, the first comparator 460 is configured to evaluate the output of the PTAT voltage generator 405, e.g. compare signal V_{ptat_ht} to the first reference voltage 490. Advantageously, by applying offset cancellation to the first comparator 460, an error contribution of the first comparator 460 to an evaluation of the output of the PTAT voltage generator 405 in the second clock phase may be reduced.

An output of the first comparator 460 is coupled to a first latch 465. The first latch 465 is also provided with the clock signal having the frequency denoted f_{az} and is configured to latch the output of the first comparator 460 at an end of the second clock phase. Thus, a precise evaluation of the die temperature may be accomplished, e.g. an indication of a high temperature condition.

The second output of the third chopper 455 is coupled to a first input of a second comparator 470, and in the example of FIG. 4 the signal to the first input of the second comparator 470 is denoted V_{ptat_ot}, and corresponds to a voltage generated at resistor R5. A second input of the second comparator 470 is coupled to the first reference voltage 490.

The second comparator 470 is also configured to apply offset cancellation by auto-zeroing during the first clock phase of the clock signal having the frequency denoted f_{az}. In the second phase of the clock signal having the frequency denoted fa, the second comparator 470 is configured to evaluate the output of the PTAT voltage generator 405, e.g. compare signal V_{ptat_ot} to the first reference voltage 490.

An output of the second comparator 470 is coupled to a second latch 475. The second latch 475 is also provided with the clock signal having the frequency denoted f_{az} and is configured to latch the output of the second comparator 470 at an end of the second clock phase. Thus, a precise evaluation of the die temperature may be accomplished, e.g. an indication of an over-temperature condition.

The second output of the third chopper 455 is coupled to a first input of a third comparator 480, and in the example of FIG. 4 the signal to the first input of the third comparator 480 is denoted V_{ptat_ut}, and corresponds to a voltage generated at resistor R4. A second input of the third comparator 480 is coupled to a second reference voltage 495.

The second reference voltage 495 may, for example, be provided by one or more separate band-gap reference voltage circuits (not shown). In the example of FIG. 4, the second reference voltage 495 is 400 mV.

The third comparator 480 is also configured to apply offset cancellation by auto-zeroing during the first clock phase of the clock signal having the frequency denoted f_{az}. In the second phase of the clock signal having the frequency denoted f_{az}, the second comparator 480 is configured to evaluate the output of the PTAT voltage generator 405, e.g. compare signal V_{ptat_ut} to the second reference voltage 495.

An output of the third comparator 480 is coupled to a third latch 485. The third latch 485 is also provided with the clock signal having the frequency denoted f_{az} and is configured to latch the output of the third comparator 480 at an end of the second clock phase. Thus, a precise evaluation of the die temperature may be accomplished, e.g. an indication of an under-temperature condition.

The particular auto-zeroing technique implemented by each of the first, second and third comparators 460, 470, 480 may operate generally be as follows. In the first clock phase, the first comparator 460 may be configured in a closed-loop configuration and a difference between a reference voltage and an offset may be stored in a capacitor. In the second clock phase, the comparator 460, 470, 480 may be configured in an open-loop configuration, and the stored voltage on the capacitor makes the comparator 460, 470, 480 almost offset free when an input signal e.g. an output from the PTAT voltage generator 405, is compared with the reference voltage. The reference voltage used for auto-zeroing may be different from the reference voltages used for comparison, e.g. the first reference voltage 490 and the second reference voltage 495.

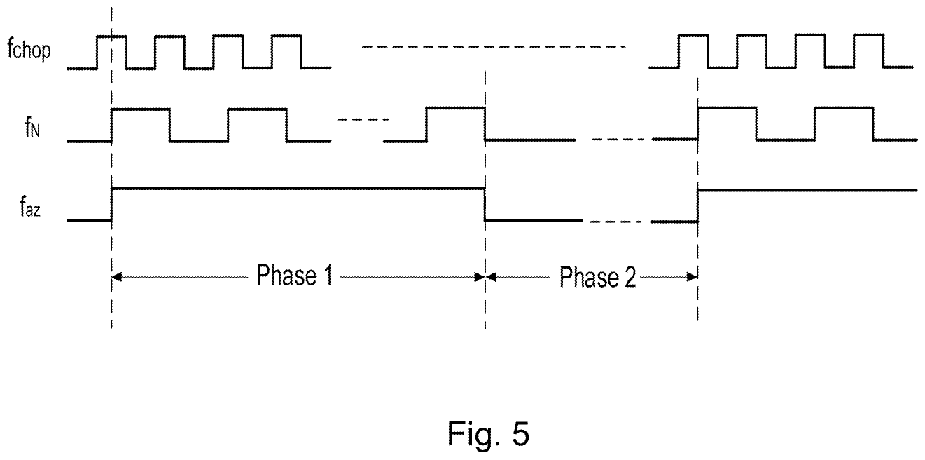

The operation of the circuit 400 is described in more detail with reference to the timing diagram of FIG. 5.

During a first phase, denoted ‘Phase 1’, of the clock signal having the frequency denoted f_{az}, chopper stabilization is applied to the PTAT generator, and auto-zeroing is applied to the comparators. Thus, a clock signal having an operating frequency denoted fₙ is provided to the notch filter 440. Also, a further clock signal having a frequency denoted f_{chop} is provided to the first and second choppers 430 and 435. The signal f_{chop} has a 50% duty cycle and twice the frequency of fₙ.

Due to the chopper stabilization, any offset of the OTA 425 is removed and an accurate PTAT current is generated in the current source by the bipolar core 410 and resistor R2.

Also, due to the auto-zeroing during the first phase, the inputs to the first, second and third comparators 460, 470, 480 will have no impact upon respective outputs of the first, second and third comparators 460, 470, 480 during the first phase, and any offsets of the comparators 460, 470, 480 are removed.

At the end of the first phase, the third chopper 455 is configured to swap the outputs of the current mirror 458. As such, a precise PTAT current will be coupled to the series of the resistors R3, R4, R5 to generate precise PTAT voltages.

At the end of the first phase, the other output of the current mirror 458, e.g. the mirrored current, is applied to the bipolar core 410. Advantageously, by coupling the mirrored current to the bipolar core 410, the output of the OTA 425 may be configured to be more stabilized ahead of the next clock phase, e.g. in the first clock phase of the next clock period.

Meanwhile the comparators 460, 470, 480 stop auto-zeroing, and start the comparison of their respective input signals as described above. In second phase, the notch filter 440 stops operating, as depicted by the lack of clock signal having a operating frequency denoted f_{Q} during the second phase in FIG. 5. As a result, the notch filter's output at the end of the first phase will be kept unchanged over the following second phase such that the outputs of the PTAT generator 405 are precise and constant over the entire second phase.

The first, second and third comparators 460, 470, 480 may take the second phase to evaluate the respective input PTAT voltages at each of resistors R3, R4 and R5. At the end of the second phase, the outputs of the first, second and third comparators 460, 470, 480 are latched by respective latches 465, 475, 485 to achieve a precise evaluation of the device temperature

Advantageously, by this approach a final accuracy of the device temperature protection may be determined mainly by an accuracy of the first reference voltage 490 and the second reference voltage 495 and by the matching between the resistors and the bipolar transistors 415, 420. For example, in a CMOS fabrication process, matching between the resistors may have errors in the region of less than 0.5%. In some example, a high accuracy of the input reference voltages 490, 495 may be achieved by single temperature trimming of a bandgap reference generator without an accurate ambient temperature. Furthermore, such a trimmed bandgap reference generator is usually required by other part of the final device. Therefore, no additional calibration or trimming is required to implement the disclosed device temperature protection.

FIG. 6 depicts an example circuit for a chopper 600. The chopper 600 may correspond to the first chopper 430, the second chopper 435 and/or the third chopper 455 of FIG. 4.

The chopper 600 has a first input 605, a second input 610, a first output 615 and a second output 620. The chopper 600 has a first switch 625, a second switch 630, and third switch 635 and a fourth switch 640. For purposes of illustration only, all of the switches 625, 630, 635, 640 and depicted as open.

In use, when a clock signal φ is in a first phase, the first switch 625 and the fourth switch 640 are closed and the second switch 630 and the third switch 635 are opened. As such, in the first phase the first input 605 is coupled to the first output 615 and the second input 610 is coupled to the second output 620.

When the clock signal φ is in a second phase, the first switch 625 and the fourth switch 640 are opened and the second switch 630 and the third switch 635 are closed. As such, in the second phase the first input 605 is coupled to the second output 620 and the second input 610 is coupled to the first output 615.

FIG. 7 depicts an example of a device 700 comprising a circuit 705. The circuit 705 corresponds to the circuit 400 of FIG. 4.

In an example use, the circuit 705 may indicate an over temperature condition. In such an over temperature condition, the circuit 705 may provide an indication to a processor 710. The processor 710 may perform an action in response to an indication of an over temperature condition. For example, in some embodiments, the processor 710 may be configured to reduce a clock frequency, or otherwise limit activities, to reduce a power consumption of the processor 710 and thus reduce a temperature of the device 700.

In yet another example use, the circuit 705 may indicate a high temperature condition. In such a high temperature condition, the circuit 705 may provide an indication to a reset circuit 715. The reset circuit 715 may perform an action in response to an indication of a high temperature condition. For example, in some embodiments, the reset circuit 715 may be configured to reset the device. Such action may reduce a power consumption of the device 700.

In yet another example use, the circuit 705 may indicate a high temperature condition. In such a high temperature condition, the circuit 705 may provide an indication to a power supply circuit, such as a voltage regulator. The power supply circuit may perform an action in response to an indication of a high temperature condition. For example, in some embodiments, the power supply circuit may be configured to reduce a voltage of, or even disable, one or more power supplies. Such action may reduce a power consumption of the device 700, and hence reduce a temperature of the device 700.

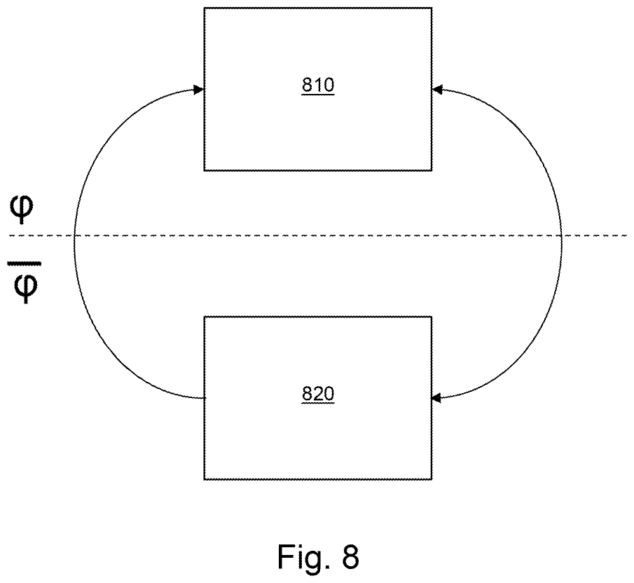

FIG. 8 depicts a method of temperature protection of a device, e.g. the device 700 of FIG. 7.

A step 810 comprises configuring a PTAT voltage generator in a circuit to apply offset cancellation in a first clock phase. For example, the first step 810 may comprise configuring the PTAT voltage generator 405 in the circuit 400 to apply offset cancellation in a first clock phase.

A step 820 comprises configuring at least one comparator in the circuit to evaluate an output of the PTAT voltage generator in a second clock phase. For example, the second step 820 may comprise configuring the first, second and third comparators 460, 470, 480 in the circuit 400 to evaluate an output of the PTAT voltage generator 405 in a second clock phase.

In some embodiments, the first step 810 may also comprise applying offset cancellation to the at least one comparator by auto-zeroing during the first clock phase.

The step 810 and the step 820 are repeated with each period of the clock, as indicated by the arrows in FIG. 8, which show that the step 810 is followed by the step 820 and the step 820 is followed by the step 810.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

100 circuit
105 CTAT sub-circuit
110 reference current input
115 reference voltage input
120 reference voltage input
125 first transistor
130 second transistor
135 bipolar transistor
140 first comparator
145 second comparator
150 exclusive NOR gate
205 CTAT voltage generator
210 analog-to-digital converter
215 processor
300 circuit
305 PTAT voltage generator
310 comparator
400 circuit
405 PTAT voltage generator
410 bipolar core
415 first BJT
420 second BJT
425 operational transconductance amplifier
430 first chopper
435 second chopper
440 notch filter
445 first transistor
450 second transistor
455 third chopper
458 current mirror
460 first comparator
465 first latch
470 second comparator
475 second latch
480 third comparator
485 third latch
490 first reference voltage
495 second reference voltage
600 chopper
605 first input
610 second input
615 first output
620 second output
625 first switch
630 second switch
635 third switch
640 fourth switch
700 device
705 circuit
710 processor
715 reset circuit
810 step
820 step

1. A circuit for device temperature protection comprising:
a Proportional-To-Absolute-Temperature (PTAT) voltage generator; and
at least one comparator;
wherein:
the PTAT voltage generator is configured to apply offset cancellation in a first clock phase; and
the at least one comparator is configured to evaluate an output of the PTAT voltage generator in a second clock phase.

2. The circuit of claim 1, wherein the PTAT voltage generator comprises an operational transconductance amplifier (OTA), and wherein the offset cancellation is applied to the PTAT voltage generator by chopper stabilization of the OTA.

3. The circuit of claim 1, wherein the at least one comparator is configured to apply offset cancellation by auto-zeroing during the first clock phase.

4. The circuit of claim 1, comprising a latch configured to latch an output from the at least one comparator at an end of the second clock phase.

5. The circuit of claim 1, wherein the PTAT voltage generator comprises a bipolar core configured to generate a current for generating the output of the PTAT voltage generator.

6. The circuit of claim 5, wherein the PTAT voltage generator comprises first and second transistors configured as a current mirror to mirror the current.

7. The circuit of claim 6, wherein the PTAT voltage generator comprises a notch filter configured to filter an output from the OTA, an output of the notch filter coupled to a gate of the first and second transistors.

8. The circuit of claim 6, wherein the PTAT voltage generator comprises a chopper coupled to a first output and a second output of the current mirror, the second output of the current mirror corresponding to a mirrored current.

9. The circuit of claim 8, wherein in the second clock phase the chopper is configured to:
couple the first output of the current mirror to a resistor to generate a voltage corresponding to the output of the PTAT voltage generator; and/or
couple the second output of the current mirror to the bipolar core.

10. The circuit of claim 9, wherein in the first clock phase the chopper is configured to:
couple the second output of the current mirror to the resistor; and/or
couple the first output of the current mirror to the bipolar core.

11. The circuit of claim 1, comprising a plurality of comparators, each comparator configured to evaluate a respective output of the PTAT voltage generator in the second clock phase by comparing the respective output to a respective reference voltage.

12. The circuit of claim 11, wherein in the second clock phase the chopper is configured to couple the first output of the current mirror to a series of resistors to generate voltages corresponding to the respective outputs of the PTAT voltage generator.

13. A device comprising the circuit of claim 1, wherein the at least one comparator is configured to compare an output of the PTAT voltage generator to a reference voltage to determine whether a temperature of the device has exceeded a limit.

14. A method of temperature protection of a device, the method comprising:
configuring a PTAT voltage generator in a circuit to apply offset cancellation in a first clock phase; and
configuring at least one comparator in the circuit to evaluate an output of the PTAT voltage generator in a second clock phase.

15. The method of claim 14 comprising:
applying the offset cancellation by chopper stabilization of an OTA in the PTAT voltage generator; and/or
applying offset cancellation to the at least one comparator by auto-zeroing during the first clock phase.
